(19) United States
(12) Patent Application Publication
(10) Pub. No.: US 2025/0174587 A1
(43) Pub. Date: May 29, 2025

(54) CONDUCTIVE BUMP AND METHOD FOR FABRICATING THE SAME

(71) Applicant: SILICONWARE PRECISION INDUSTRIES CO., LTD., Taichung City (TW)

(72) Inventors: Yen-Hao SU, Taichung City (TW); Pang-Chun LIN, Taichung City (TW); Hsuan-Min SU, Taichung City (TW)

(73) Assignee: SILICONWARE PRECISION INDUSTRIES CO., LTD., Taichung City (TW)

(21) Appl. No.: 18/895,782

(22) Filed: Sep. 25, 2024

(30) Foreign Application Priority Data
Nov. 29, 2023 (TW) 112146375

(51) Int. Cl. H01L 23/00

(52) U.S. Cl. CPC H01L 24/13; H01L 24/11; H01L 2224/1147; H01L 2224/11849; H01L 2224/1308; H01L 2224/13111; H01L 2224/13139; H01L 2224/13147; H01L 2224/13155

(57) ABSTRACT

Provided are a conductive bump and its fabricating method, including: forming a first metal layer, a second metal layer, a barrier metal layer, and a third metal layer on a bonding pad of a semiconductor substrate in sequence. The first metal layer is a copper layer, the second metal layer is a nickel layer, the barrier metal layer is a copper layer, and the third metal layer is a tin-silver alloy layer. The metal migration problem can be prevented by adding the barrier metal layer between the third metal layer and the second metal layer.

### BACKGROUND

### 1. Technical Field

The present disclosure relates to a conductive bump, and more particularly, to a conductive bump formed on a semiconductor substrate and the method for fabricating the same.

### 2. Description of Related Art

Compared with wire bonding technology, the characteristic of flip chip package is that the electrical connection between the semiconductor chip and the packaging substrate is through solder bumps instead of ordinary gold wires. Using solder bumps as the electrical connection components has the advantages of shortening the paths of electrical conduction, improving performance, providing the paths for heat dissipation, and reducing package volume, and therefore has become the trend of package.

Please refer to FIG. 1A to FIG. 1C, the existing process of forming solder bumps for wafers/chips is to form a copper layer (Cu) 11/a nickel layer (Ni) 12/a tin-silver alloy layer (Sn—Ag) 13 on a bonding pad 10 in sequence first, followed by performing a reflow soldering process, and then to perform a wafer level test (Wafer Sort). At this point, the coplanarity of the solder bumps is poor due to the indentation 130 by the test probe and the melting of the solder, which easily causes non-wet problems during the flip-chip operation.

To solve the problem of indentations by the test probes, the reflow soldering process is performed after the wafer-level test in the industry. However, migration of nickel to the surface of the solder bump during power-on when the wafer level test is performed first, a mark would be left, and the nickel could not be removed after completion of the test.

Therefore, how to overcome the above-mentioned problems of conventional techniques has become an urgent issue to be solved.

### SUMMARY

In view of the aforementioned shortcomings of the prior art, the present disclosure provides a conductive bump formed on a bonding pad of a semiconductor substrate, including: a first metal layer, being a copper layer and disposed on the bonding pad; a second metal layer, being a nickel layer and disposed on the first metal layer; a barrier metal layer, being a copper layer and disposed on the second metal layer; and a third metal layer, being a tin-silver alloy layer and disposed on the barrier metal layer.

The present disclosure further provides a method for fabricating a conductive bump. The method includes: providing a semiconductor substrate with a plurality of bonding pads, and forming a conductive metal layer that covers the plurality of bonding pads on the semiconductor substrate; forming a photoresist layer on the conductive metal layer, and forming a plurality of openings on the photoresist layer, wherein each of the openings corresponds to the position of each of the bonding pads; forming a first metal layer, a second metal layer, a barrier metal layer, and a third metal layer in sequence by plating on the conductive metal layer within each of the openings, wherein the first metal layer is a copper layer, the second metal layer is a nickel layer, the barrier metal layer is a copper layer, and the third metal layer is a tin-silver alloy layer; removing the photoresist layer and the conductive metal layer covered by photoresist layer; and performing a reflow soldering process to form the conductive bump on each of the bonding pads.

The aforementioned conductive bump and fabricating method further include a fourth metal layer and a fifth metal layer formed in sequence between the second metal layer and the barrier metal layer, wherein the fourth metal layer is a tin-silver alloy layer and the fifth metal layer is a nickel layer.

The aforementioned conductive bump and fabricating method further include a fourth metal layer formed between the second metal layer and the barrier metal layer, wherein the fourth metal layer is a tin-silver alloy layer.

The aforementioned conductive bump and fabricating method further include forming a first intermetallic compound between the second metal layer and the barrier metal layer and forming a second intermetallic compound between the barrier metal layer and the third metal layer after performing the reflow soldering process.

It can be seen from above, the conductive bump and its fabricating method of the present disclosure mainly add the barrier metal layer (a copper layer) in the third metal layer (a tin-silver alloy layer) and the second metal layer (a nickel layer). Also, and the present disclosure forms the first intermetallic compound between the second metal layer and the barrier metal layer, and forms the second intermetallic compound between the barrier metal layer and the third metal layer after the reflow soldering process, thereby preventing the metal (nickel) migration, and thus solving the shortcomings such as non-wet, etc., of conventional solder bumps caused by the poor coplanarity due to probe indentation.

### BRIEF DESCRIPTION OF THE DRAWINGS

FIG. 1A to FIG. 1C are schematic cross-sectional views of the fabricating processes of a conventional solder bump.

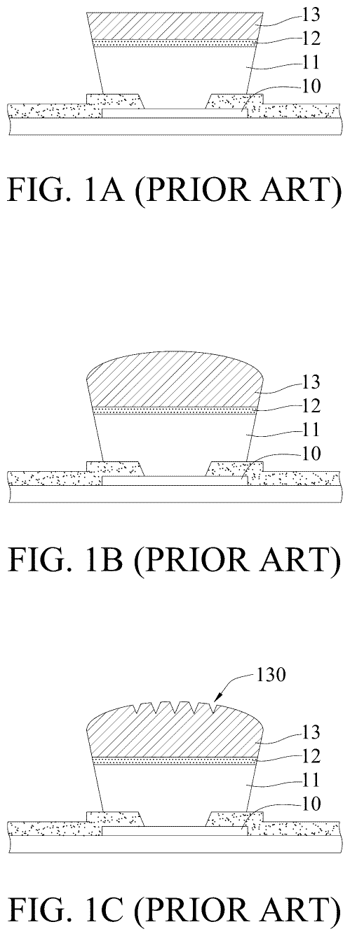

FIG. 2A to FIG. 2F are schematic cross-sectional views of a first embodiment of the fabricating method of the conductive bump of the present disclosure.

FIG. 3 is a schematic cross-sectional view of a second embodiment of the conductive bump of the present disclosure.

FIG. 4 is a schematic cross-sectional view of a third embodiment of the conductive bump of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

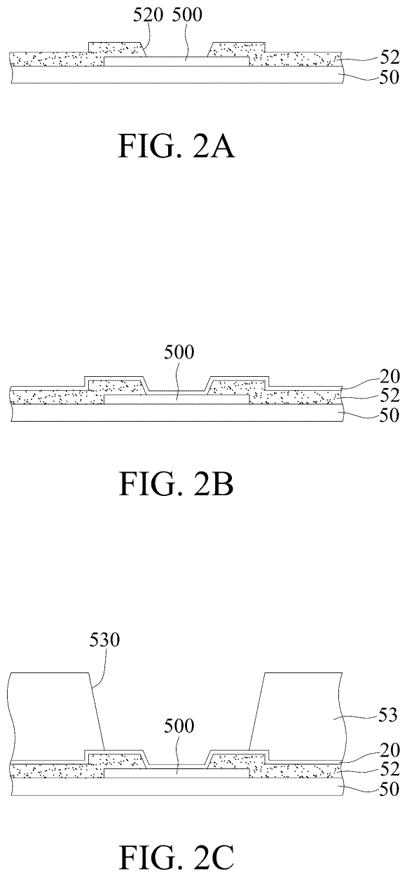

Please refer to FIG. 2A to FIG. 2F, which are schematic cross-sectional views of a first embodiment of the fabricating method of the conductive bump of the present disclosure. The conductive bump is formed on a semiconductor substrate such as a wafer or a chip.

As shown in FIG. 2A, providing a semiconductor substrate 50 with a plurality of bonding pads 500. Since the processes performed on each of the bonding pads 500 are the same, therefore only one bonding pad 500 is shown in the drawings as a representative.

In this embodiment, the semiconductor substrate 50 is a wafer, while the semiconductor substrate 50 may also be a silicon substrate or a glass substrate in other embodiments. The semiconductor substrate 50 is covered with an insulation layer 52, and the insulation layer 52 has a plurality of holes 520, such that each of the bonding pads 500 is corresponding to and exposed from the holes 520. In addition, the bonding pad 500 may be formed by aluminum, and t the insulation layer 52 may be formed by Silicon Nitride (SiN) or a silicon-oxygen compound (SiOX) to be used as a passivation layer.

As shown in FIG. 2B, forming a conductive metal layer 20 on the insulation layer 52 and each of the bonding pads 500 next. The conductive metal layer 20 is used as the current-conducting path needed for the metal material platting described later, and the conductive metal layer 20 may be formed by titanium/copper (Ti/Cu) or titanium/tungsten/copper (Ti/W/Cu).

As shown in FIG. 2C, forming a photoresist layer 53 on the conductive metal layer 20. Next, forming a plurality of openings 530 on the photoresist layer 53 through an exposure and development processes, and each of the openings 530 corresponds to a position of the bonding pad, thereby the conductive metal layer 20 on each of the bonding pads 500 is exposed from each of the openings 530.

As shown in FIG. 2D, forming a first metal layer 21, a second metal layer 22, a barrier metal layer B2, and a third metal layer 23 by plating in sequence on the conductive metal layer 20 within each of the openings 530. In this embodiment, the first metal layer 21 is a copper (Cu) layer, the second metal layer 22 is a nickel (Ni) layer, the barrier metal layer B2 is a copper (Cu) layer, and the third metal layer 23 is a tin-silver alloy (SnAg) layer.

As shown in FIG. 2E, removing the photoresist layer 53 and the conductive metal layer 20 beneath it.

In this embodiment, the conductive metal layer 20 left on the bonding pad 500 can be used as a under bump metallization layer (UBM).

As shown in FIG. 2F, performing a reflow soldering process, such that a first intermetallic compound (IMC) I1 is formed between the second metal layer 22 (a nickel layer) and the barrier metal layer B2 (a copper layer), and a second intermetallic compound 12 is formed between the barrier metal layer B2 (a copper layer) and the third metal layer 23 (a tin-silver alloy layer), to form the conductive bump 2 of the present disclosure.

Accordingly, the conductive bump 2 of the present disclosure mainly adds the barrier metal layer B2 (a copper layer) between the third metal layer 23 (a tin-silver alloy layer) and the second metal layer 22 (a nickel layer), and form the first intermetallic compound I1 and the second intermetallic compound 12 after the reflow soldering process, to prevent the metal (nickel) migration, then solve the shortcomings of conventional solder bumps such as non-wet caused by the poor coplanarity due to probe indentation.

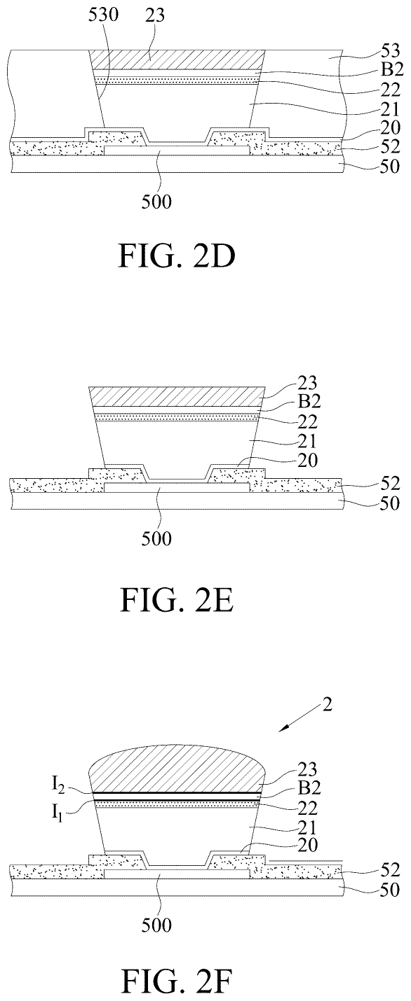

Please refer to FIG. 3, which is a schematic cross-sectional view of a second embodiment of a conductive bump 3 of the present disclosure. The main differences between the present embodiment and the first embodiment are the changes in the numbers and the locations of the metal layers and the barrier metal layer, while the other related processes are roughly the same and thus are omitted herein.

Besides the first metal layer (such as a copper layer) 31, the second metal layer (such as a nickel layer) 32, the barrier metal layer (such as a copper layer) B3, and the third metal layer (such as a tin-silver alloy layer) 33 described above, the conductive bump 3 of the present embodiment further includes a fourth metal layer (such as a tin-silver alloy layer) 34 and a fifth metal layer (such as a nickel layer) 35 formed in sequence between the second metal layer (such as a nickel layer) 32 and the barrier metal layer (such as a copper layer) B3.

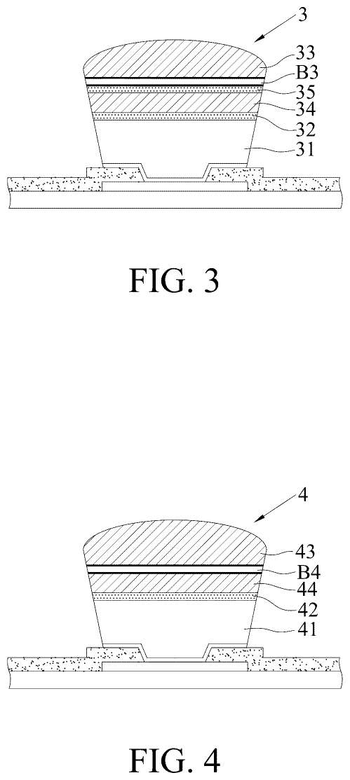

Please refer to FIG. 4, which is a schematic cross-sectional view of the third embodiment of a conductive bump 4 of the present disclosure. The main differences between the present embodiment and the first embodiment are the changes in the numbers and the locations of the metal layers and the barrier metal layer, while the other related processes are roughly the same and thus are omitted herein.

Besides the first metal layer (such as a copper layer) 41, the second metal layer (such as a nickel layer) 42, the barrier metal layer (such as a copper layer) B4, and the third metal layer (such as a tin-silver alloy layer) 43 described above, the conductive bump 4 of the present embodiment further includes a fourth metal layer (such as a tin-silver alloy layer) 44 formed between the second metal layer (such as a nickel layer) 42 and the barrier metal layer (such as a copper layer) B4.

In summary, the conductive bump and its fabricating method of the present disclosure mainly add the barrier metal layer in a plurality of metal layers, and form the intermetallic compounds after the reflow soldering process, to prevent the metal migration, thereby solve the shortcomings such as non-wet, etc., of the conventional solder bumps caused by the poor coplanarity due to probe indentation.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A conductive bump formed on a bonding pad of a semiconductor substrate, including:
a first metal layer, being a copper layer and disposed on the bonding pad;
a second metal layer, being a nickel layer and disposed on the first metal layer;
a barrier metal layer, being a copper layer and disposed on the second metal layer; and
a third metal layer, being a tin-silver alloy layer and disposed on the barrier metal layer.

2. The conductive bump of claim 1, further including a fourth metal layer and a fifth metal layer formed in sequence between the second metal layer and the barrier metal layer, wherein the fourth metal layer is a tin-silver alloy layer and the fifth metal layer is a nickel layer.

3. The conductive bump of claim 1, further including a fourth metal layer formed between the second metal layer and the barrier metal layer, wherein the fourth metal layer is a tin-silver alloy layer.

4. The conductive bump of claim 1, further including a first intermetallic compound formed between the second metal layer and the barrier metal layer, and a second intermetallic compound formed between the barrier metal layer and the third metal layer.

5. A method for fabricating a conductive bump, including:
providing a semiconductor substrate with a plurality of bonding pads, and forming a conductive metal layer covering the plurality of bonding pads on the semiconductor substrate;
forming a photoresist layer on the conductive metal layer, and forming a plurality of openings penetrating the photoresist layer, wherein each of the openings corresponds to a position of each of the bonding pads;
forming a first metal layer, a second metal layer, a barrier metal layer, and a third metal layer in sequence by plating on the conductive metal layer within each of the openings, wherein the first metal layer is a copper layer, the second metal layer is a nickel layer, the barrier metal layer is a copper layer, and the third metal layer is a tin-silver alloy layer;
removing the photoresist layer and the conductive metal layer covered by photoresist layer; and
performing a reflow soldering process to form the conductive bump on each of the bonding pads.

6. The method of claim 5, further including forming a fourth metal layer and a fifth metal layer in sequence between the second metal layer and the barrier metal layer, wherein the fourth metal layer is a tin-silver alloy layer, and the fifth metal layer is a nickel layer.

7. The method of claim 5, further including forming a fourth metal layer between the second metal layer and the barrier metal layer, wherein the fourth metal layer is a tin-silver alloy layer.

8. The method of claim 5, further including after performing the reflow soldering process, forming a first intermetallic compound between the second metal layer and the barrier metal layer, and forming a second intermetallic compound between the barrier metal layer and the third metal layer.
